(19) United States
(12) Patent Application Publication
(10) Pub. No.: US 2025/0154640 A1
(43) Pub. Date: May 15, 2025

(54) METHOD AND DEVICE FOR COATING POWDER- OR GRANULAR-FORM PARTICLES

(71) Applicant: Rainer Cremer, Monschau (DE)

(72) Inventor: Rainer Cremer, Monschau (DE)

(21) Appl. No.: 18/838,409

(22) PCT Filed: Jan. 2, 2023
(86) PCT No.: PCT/DE2023/100000

§ 371 Date: Aug. 14, 2024

(30) Foreign Application Priority Data
Feb. 22, 2022 (DE) 10 2022 104 093.3

(51) Int. Cl. C23C 14/22; C23C 14/34

(52) U.S. Cl. CPC C23C 14/223; C23C 14/3485

(57) ABSTRACT

The invention relates to a method and a device for coating powder- or granular-form particles by means of gas flow sputtering with a hollow cathode functioning as a target, which is arranged in an evacuable container together with an anode and a collection container. In order to work efficiently and with easier handling, it is proposed that after a metered introduction into an inlet opening, the powder- or granular-form particles to be coated pass through the evacuated interior of the hollow cathode in a free fall of 0.3 m to 1 m and are collected in a lower collection container.

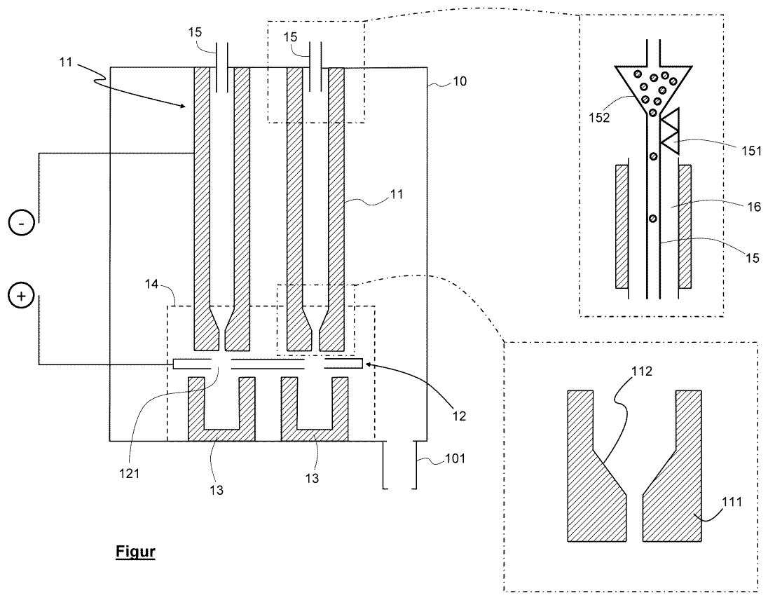

### FIELD OF THE INVENTION

The invention relates to a method and a device for coating powder- or granular-form particles by means of gas flow sputtering with a hollow cathode functioning as a target, which is arranged in an evacuable container together with an anode and a collection container.

### BACKGROUND OF THE INVENTION

In gas flow sputtering, the material to be atomized is placed in a vacuum in the form of a “target”. A noble gas plasma, usually with argon, is ignited in the process container, wherein the target is switched as the anode of the discharge. Due to the intense bombardment of the target surface with noble gas ions, the target material is atomized and condenses on the substrates present in the chamber. The sputtering can be carried out at relatively low temperatures. Such a method is described, for example, in DE 196 35 669 C1. For this purpose, a device is used which possesses a hollow cathode functioning as a target. Inert gas is introduced into the hollow cathode interior via an inflow device, which generates the desired hollow cathode glow discharge. If necessary, an additional quantity of charge carriers can be introduced by means of an additional hollow cathode. With the inert gas flow, the particles dusted from the cathode pass through a housing opening onto the substrate arranged behind the opening, on which the particles released from the target are deposited and form a coating.

DE 198 04 838 A1 describes a method in which particulate materials such as metals, metal alloys, inorganic oxides, silicates and zeolites are provided with a metal coating, e.g. of cobalt, vanadium, copper or stainless steel. For this purpose, a hollow cathode plasma source consisting of a cathode material with a cavity arranged therein and an anode material arranged in close proximity and isolated therefrom is to be used, wherein the cavity is a single cavity or a plurality of cavities and the cavity extends both individually and in the plurality continuously from one side to another side of the cathode material, is open on both sides and at least partially has an essentially cylindrical cross-section with a diameter of 0.1 mm to 20 mm of the single cavity. In order to ensure sufficient coating of the powder-form material in the plasma in the cathode cavity, the material to be coated should be passed through the plasma several times.

Based on this, it is the task of the present invention to provide a method and a device that works more efficiently and is easy to handle.

This task is solved by a method according to claim 1 or by the device according to claim 6.

According to the invention, after a metered introduction into an inlet opening, the powder- or granular-form particles to be coated are guided into the evacuated interior of the hollow cathode, where they pass through a distance of 0.3 m to 1 m in free fall and are collected in a lower collection container. For this purpose, the evacuable container possesses a hollow cathode functioning as a target and an anode as well as a collection container. The evacuable container for coating the material has an inlet opening in the upper area for the powder- or granular-form particles as well as for a gas or gas mixture, which opens into the hollow cathode with a vertical length of 0.5 m to 1 m, below which the collection container(s) for the coated particles are arranged. Due to the set vacuum with a pressure of a few Pa, the powder introduced into the cathode interior has a gravitational acceleration of 9.81 m/s². The drop time is approx. 0.3 s at a drop height of 0.5 m and 0.45 s at a drop height of 1 m. This means that a fivefold increase in the drop height does not result in significantly longer coating times. Overall, high deposition rates can therefore be achieved with a single pass through a hollow cathode. Further preferable measures result from the sub-claims. For example, a pulsed plasma is preferably used, which can increase the process stability.

According to a further embodiment of the invention, the particles to be coated are introduced together with a gas or a gas mixture, wherein the particles are preferably introduced via a centrally arranged tube and the gas or gas mixture is introduced via an annular space extending around the tube for the particle supply. This measure allows a turbulent behavior of the powder- or granular-form particles to be set, so that a uniform coating is ensured due to the incoming turbulence of these particles.

The diameter of the hollow cathode is tapered at the lower outlet, which prevents uncontrolled discharge of the atomizing material and stabilizes the cathode. The coating material that is not deposited on the powder- or granular-form particles is deposited again on the opposite side of the hollow cathode, so that a stationary state is achieved if there is no or insufficient particle flow. The tapering of the hollow cathode interior at the lower outlet also prevents uncontrolled discharge of the atomizing material and prevents particle deposits inside the cathode.

According to a further embodiment of the invention, the backflow of the coated powder is prevented by a net which extends from the collection container into an area above the outlet of the hollow cathode.

Preferably, the device according to the invention possesses a hollow cathode inner diameter of 10 mm to 30 mm and an outlet opening of the hollow cathode with a diameter of 4 mm to 6 mm, preferably 5 mm. The tapered diameter of the cathode interior is realized in a preferably detachably attached lid with a conical interior. The detachably fastened lid, which can be screwed on, for example, can thus be easily replaced or cleaned. As already mentioned, a mesh with a suitable mesh size is preferably used to prevent backflow of the coated powder.

The anode as well as the hollow cathode are water-cooled. The hollow cathode has a (target) insert, which can be made of precious metal, for example. The anode extends into the area below the hollow cathode and possesses holes to allow the passage of coated particles. These openings are preferably 30 mm to 40 mm in diameter.

According to a further embodiment of the invention, a dosing device for the particle supply is provided above the inlet opening for the powder- or granular-form particles, in which in particular a vibrator as well as an adjustable valve are arranged. This makes it possible both to avoid material jams and to ensure a uniform particle supply. In a particular embodiment of the invention, the particle inlet, which projects into the hollow cathode interior, consists of a tube with a diameter of 0.8 mm to 1.2 mm (preferably 1 mm), which is arranged centrally to an annular space formed as a gas inlet with a diameter of between 3 mm and 5 mm. This dimensioning has the advantage that the formation of a “burning plasma” in the inlet area is avoided and thus no melting of the introduced particles can occur.

The efficiency of the device is optimized by arranging several hollow cathodes in parallel in a cathode array, which are surrounded by a common (ring) anode. Each of these hollow cathodes has an inlet opening for the particles and the gas or gas mixture. In this way, several hollow cathodes can perform coatings. A collection container is located under each hollow cathode. To ensure that the device can be sufficiently evacuated before the coating process, a rotary vane pump or a combination of a rotary vane pump and a Roots pump is preferably used. Only after the required negative pressure (vacuum) has been reached, the particle and gas supply is released via the existing valve or valves. The vacuum chamber and the collection containers are potential-free. The selected power consumption per hollow cathode is approx. 2 KW to 8 KW, preferably 3 KW to 6 kW.

In specific embodiments, for example, an Al₂O₃ powder has been coated with Cu. The Al₂O₃ powder had a grain size corresponding to a mesh width of 500. SiC, WC graphite or Ti₃O₅ powders, for example, could be coated just as well.

### BRIEF DESCRIPTION OF THE DRAWING

The only FIGURE shows a schematic structure of a device consisting of an evacuable container 10 with two water-cooled hollow cathodes 11 and a water-cooled anode 12, which extends into the area below the hollow cathodes 11 and possesses holes 121 through which the coated powder or granular-form material can pass into one of the two collection containers 13 shown.

### DETAILED DESCRIPTION OF THE PREFERRED EMBODIMENTS

The mesh 14, which is also shown, surrounds both the collection containers 13 all around and extends upwards into an area above the outlet openings 121 of the hollow cathode interiors. The powder is supplied via tubular inlets 15, which are surrounded by an annular space 16 concentrically arranged for gas supply. The entire container 10 can be evacuated via a pump, preferably a combination of a rotary vane pump and a Roots pump, which is connected to the outlet 101. The tubes 15 for supplying the powder-form particles have both a controllable valve 151 and a vibrator 152, which causes the feed hopper to vibrate, preventing clumping during the powder supply.

The hollow cathode possesses a lid 111 in its lower area, which can be unscrewed and is attached to the rest of the hollow cathode. This lid possesses a tapering 112 of the interior, by which the hollow cathode inner diameter is reduced from a width of 1.5 cm to 3 cm to a diameter of approx. 5 mm.

1. A method for coating powder- or granular-form particles by means of gas flow sputtering with a hollow cathode functioning as a target, wherein
the powder- or granular-form particles to be coated, after a metered introduction into an inlet opening pass through the evacuated interior of the hollow cathode in free fall of 0.3 m to 1 m and are collected in a lower collection container.

2. The method according to claim 1, wherein a pulsed plasma is set in the interior of the hollow cathode.

3. The method according to claim 1, wherein the particles to be coated are introduced together with a gas or a gas mixture.

4. The method according to claim 1, wherein the diameter of the hollow cathode tapers at the lower outlet.

5. The method according to claim 1, wherein the backflow of the coated powder is prevented by a net which extends from the collection container to an area above an outlet of the hollow cathode.

6. A device for coating powder- or granular-form particles by means of gas flow sputtering with an evacuable container in which a hollow cathode functioning as a target and an anode as well as collection containers are arranged,
wherein
the container has an inlet opening in the upper area for powder- or granular-form particles and for a gas or a gas mixture, which opens into the hollow cathode with a vertical length of 0.3 m to 1 m, below which the collection containers for the coated particles are arranged.

7. The device according to claim 6, wherein the inner diameter of the cathode is between 10 mm and 30 mm and the outlet opening possesses a diameter of 4 mm to 6 mm.

8. The device according to claim 6, wherein a net is arranged in the container, which extends from the collection container to an area above an outlet of the hollow cathode and serves to retain the coated powder.

9. The device according to claim 6, wherein the anode is water-cooled and extends into the area below the hollow cathode, where the anode has holes for the passage of particles.

10. The device according to claim 6, wherein, characterized in that the inner surface of the hollow cathode functioning as a target is replaceably arranged and preferably consists of precious metal.

11. The device according to claim 6, wherein, characterized in that a dosing device for the particle supply is provided above the inlet opening.

12. The device according to claim 6, wherein, characterized in that a tube with an internal diameter of 0.8 mm to 1.2 mm that serves to introduce the particles into the hollow cathode interior is provided which is arranged centrally to an internal space formed as a gas inlet with an internal diameter of between 3 mm and 5 mm.

13. The device according to claim 6, wherein characterized in that several hollow cathodes are arranged in parallel in a cathode array, which are surrounded by a common (ring) anode.

14. The device according to claim 6, characterized by having, characterized by a power consumption of 2 KW to 8 kW.

15. The device according to claim 6, wherein that a rotary vane pump or a combination of a rotary vane pump and a Roots pump is used for evacuation.

16. The method according to claim 3, wherein the particles are introduced into the hollow cathode interior via a centrally arranged tube and the gas or gas mixture is introduced via an annular space extending around the tube.

17. The device according to claim 7, wherein the outlet opening possesses a diameter of 5 mm.

18. The device according to claim 7, wherein the diameter tapering of the cathode interior is realized in a detachably attached lid with a conical interior.

19. The device according to claim 11, wherein a vibrator and an adjustable valve are arranged in the dosing device.

20. The device according to claim 14, characterized by a power consumption of 3 KW to 6 kW.
